(19) United States
(12) Patent Application Publication
(10) Pub. No.: US 2014/0367670 A1
(43) Pub. Date: Dec. 18, 2014

(54) SURFACE SEALING AGENT FOR ORGANIC EL ELEMENT, ORGANIC EL DEVICE USING SAME, AND MANUFACTURING METHOD FOR SAME

(71) Applicant: Mitsui Chemicals, Inc., Minato-ku, Tokyo (JP)

(72) Inventors: Yugo Yamamoto, Chiba-shi (JP); Jun Okabe, Ichihara-shi (JP)

(21) Appl. No.: 14/377,224

(22) PCT Filed: Feb. 7, 2013
(86) PCT No.: PCT/JP2013/000685

§ 371 Date: Aug. 7, 2014

(30) Foreign Application Priority Data
Feb. 10, 2012 (JP) 2012-027386

(51) Int. Cl. H01L 51/52; C09D 163/00; H01L 27/32; H01L 51/50; H01L 51/56

(52) U.S. Cl. CPC H01L 51/5246; H01L 51/5012; H01L 51/56; H01L 27/32; C09D 163/00
USPC 257/40; 438/28; 523/400

(57) ABSTRACT

The present invention addresses the issue of providing a surface sealing agent which can be cured at low temperatures and which exhibits excellent storage stability. In order to resolve this issue, provided is a surface sealing agent for an organic EL element, the surface sealing agent including an epoxy resin (A) having at least two epoxy groups in a molecule, and a curing accelerator (B) which is a salt of a specific quaternary ammonium ion, wherein 0.1-10 parts by weight of the curing accelerator (B) is contained relative to 100 parts by weight of the surface sealing agent.

### TECHNICAL FIELD

The present invention relates to a surface sealing agent for an organic EL element, an organic EL device using the same, and a method for manufacturing the same.

### BACKGROUND ART

Organic EL elements are organic semiconductor devices and are expected to be used as backlights for liquid crystal displays and self-luminous thin flat display devices. However, the organic EL elements are extremely easily degraded when exposed to moisture or oxygen. Specifically, the metal electrode and the organic EL layer are separated from each other at their interface by the influence of moisture, metal is oxidized to cause an increase in resistance, or organic matter itself is deteriorated by moisture. For these reasons, organic EL elements have the drawbacks of loss of luminescence and reduced luminance.

Many methods for protecting organic EL elements from water and oxygen have been reported, one of which involves surface-sealing of the organic EL element with a transparent resin layer. In this technique, a resin composition is attached or applied to an organic EL element, and then the resin composition is heat-cured for surface-sealing of the organic EL element. However, if the temperature during heat curing is high, the organic EL element is thermally degraded. Therefore, surface sealing agents have been proposed that are curable at low temperatures, which contain as the main components (A) a compound having a glycidyl group and (B) an acid anhydride curing agent (for example, see PTL 1).

Moreover, quaternary ammonium salts are generally known for example as catalysts for isocyanurate-forming reaction, cationic surfactants, and the like (for example, see PTLS 2 and 3).

When organic EL elements are used in portable electronic devices, lighting fixtures and the like, the organic EL elements are required to have weather resistance because they are exposed to daylight for a long time. In particular, if a cured product of a surface sealing agent for an organic EL element is discolored, the coupling-out efficiency will be reduced in the case of top emission type organic EL elements. Discoloration also reduces the quality of appearance of the organic EL element. Also in the case of a back emission type organic EL element, if a cured product of a surface sealing agent is discolored, discoloration reduces the quality of appearance.

### CITATION LIST

### Patent Literature

PTL 1

Japanese Patent Application Laid-Open No. 2006-70221

PTL 2

Japanese Patent Application Laid-Open No. 2011-231307

PTL 3

Japanese Patent Application Laid-Open No. 2010-129968

### SUMMARY OF INVENTION

### Technical Problem

The surface sealing agent described in PTL 1 is excellent in low-temperature curability, and a cured film thereof has high optical transparency. However, compositions which are easily cured at low temperatures tend to undergo curing reaction during storage and transportation and thus have the drawback of poor storage stability. The present invention, which has been made in view of the above-described problems, provides a surface sealing agent which is curable at low temperatures, and excellent in storage stability as well as in weather resistance.

### Solution to Problem

A first aspect of the present invention relates to a surface sealing agent for an organic EL element and a cured product thereof to be described below.

[1] A surface sealing agent for an organic EL element including: an epoxy resin (A) having two or more epoxy groups in a molecule; and a curing accelerator (B) including at least one compound selected from the group consisting of a salt (B1) of a quaternary ammonium ion represented by the following general formula (1):

### [Formula 1]

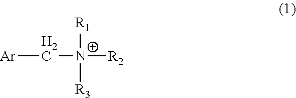

(where R₁, R₂, and R₃ each independently represent a C₁₋₁₀ alkyl group which may have a substituent, a C₆₋₁₀ aryl group which may have a substituent, or a C₇₋₂₀ aralkyl group which may have a substituent, and Ar represents a C₆₋₁₀ aryl group which may have a substituent) and a salt (B2) of a quaternary ammonium ion represented by the following general formula (2):

### [Formula 2]

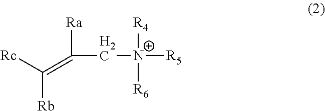

(where R₄, R₅, and R₆ each independently represent a C₁₋₁₀ alkyl group which may have a substituent, a C₆₋₁₀ aryl group which may have a substituent, or a C₇₋₂₀ aralkyl group which may have a substituent, and Ra, Rb, and Rc each independently represent a hydrogen group, a C₁₋₁₀ alkyl group, a C₁₋₁₀ alkoxy group, F, Cl, Br, I, NO₂, CN, or a group represented by the following general formula (3):

### [Formula 3]

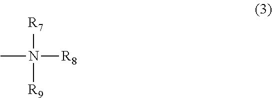

(where R₇, R₈, and R₉ each independently represent a hydrogen group or a C₁₋₁₀ hydrocarbon group)), wherein 0.1 to 10 parts by weight of the curing accelerator (B) is contained based on 100 parts by weight of the surface sealing agent.

[2] The surface sealing agent according to [1], wherein a substituent bonded to Ar in the general formula (1) is a functional group selected from the group consisting of a C₁₋₁₀ alkyl group, a C₁₋₁₀ alkoxy group, F, Cl, Br, I, NO₂, CN, and a group represented by the following general formula (4):

### [Formula 4]

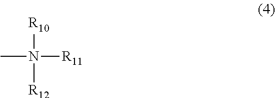

(where R₁₀, R₁₁, and R₁₂ each independently represent a hydrogen group or a C₁₋₁₀ hydrocarbon group).

[3] The surface sealing agent according to [2], wherein a substituent bonded to Ar in the general formula (1) is a functional group selected from the group consisting of a C₁₋₁₀ alkyl group, a C₁₋₁₀ alkoxy group, and a group represented by the general formula (4).

[4] The surface sealing agent according to any one of [1] to [3], wherein a substituent on R₁, R₂, and R₃ in the general formula (1) and a substituent on R₄, R₅, and R₆ in the general formula (2) are each independently a functional group selected from the group consisting of a C₁₋₁₀ alkyl group, a C₁₋₁₀ alkoxy group, F, Cl, Br, I, NO₂, CN, and a group represented by the following general formula (5):

### [Formula 5]

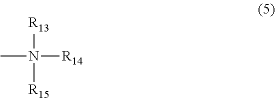

(where R₁₃, R₁₄, and R₁₅ each independently represent a hydrogen group or a C₁₋₁₀ hydrocarbon group).

[5] The surface sealing agent according to any one of [1] to [4], wherein a counter anion of the salt (B1) or the salt (B2) is selected from the group consisting of [CF₃SO₃]⁻, [C₄F₉SO₃]⁻, [PF₆]⁻, [AsF₆]⁻, [Ph₄B]⁻, Cl⁻, Br⁻, I⁻, [OC(O)R₁₆]³¹ where R₁₆ represents a C₁₋₁₀ alkyl group), [SbF₆]⁻, [B(C₆F₅)₄]₋, [B(C₆H₄CF₃)₄]⁻, [(C₆F₅)₂BF₂]⁻, [C₆F₅BF₃]⁻, and [B(C₆H₃F₂)₄]⁻. [6] The surface sealing agent according to any one of [1] to [5], further including a silane coupling agent (C).

[7] A cured product of the surface sealing agent according to any one of [1] to [6].

A second aspect of the present invention relates to an organic EL device and a method for manufacturing the same to be described below.

[8] An organic EL device including: a display substrate on which an organic EL element is disposed; a counter substrate making a pair with the display substrate; and a sealing member which is present between the display substrate and the counter substrate and seals the organic EL element, wherein the sealing member is a cured product according to [7].

[9] An organic EL panel including the organic EL device according to [8].

[10] A method for manufacturing an organic EL device, including: preparing a display substrate on which an organic EL element is disposed; covering the organic EL element with a surface sealing agent according to any one of [1] to [6]; and heat-curing the surface sealing agent.

[11] The method for manufacturing an organic EL device according to [10], further including forming a passivation film on the cured product of the surface sealing agent. [12] An organic EL device, including: an organic EL element; a cured product layer which is in contact with the organic EL element and surface-seals the organic EL element, the cured product layer including a cured product of a surface sealing agent according to any one of [1] to [6]; and a passivation film in contact with the cured product layer.

### Advantageous Effects of Invention

The surface sealing agent of the present invention contains a curing accelerator containing an ammonium salt having a specific structure and can be sufficiently cured at low temperatures. Therefore, an organic EL element can be surface-sealed without damage. Further, the cured product of the surface sealing agent of the present invention is also excellent in weather resistance and plasma resistance. Furthermore, this surface sealing agent is also excellent in storage stability and hardly cured during transportation and storage.

### BRIEF DESCRIPTION OF DRAWINGS

FIGS. 1A and 1B are schematic sectional views of a surface-sealed organic EL device;

FIGS. 2A to 2D illustrate an example of a process for manufacturing a surface-sealed organic EL device; and

FIGS. 3A to 3C illustrate another example of a process for manufacturing a surface-sealed organic EL device.

### DESCRIPTION OF EMBODIMENTS

1. Surface Sealing Agent For Organic EL Element

The surface sealing agent of the present invention contains an epoxy resin (A) and a curing accelerator (B) containing a salt of a specific quaternary ammonium, and may further contain a silane coupling agent (C) and the like.

Epoxy Resin (A)

Epoxy resin (A) contained in the surface sealing agent of the present invention may be an epoxy resin having two or more epoxy groups in a molecule. The molecular weight of the epoxy resin is not particularly limited; epoxy resins either with or without molecular weight distribution can be used.

Examples of the epoxy resin having two epoxy groups in a molecule include hydroquinone diglycidyl ether, resorcinol diglycidyl ether, ethylene glycol diglycidyl ether, polyethylene glycol diglycidyl ether, 1,4-butanediol diglycidyl ether, 1,6-hexanediol diglycidyl ether, cyclohexanediol diglycidyl ether, cyclohexanedimethanol diglycidyl ether, dicyclopentadienediol diglycidyl ether, 1,6-naphthalenediol diglycidyl ether, bisphenol A diglycidyl ether, bisphenol F diglycidyl ether, hydrogenated bisphenol A diglycidyl ether, and hydrogenated bisphenol F diglycidyl ether.

Examples of a compound having three or more epoxy groups in a molecule include trimethylolpropane triglycidyl ether, pentaerythritol tetraglycidyl ether, phenol novolac epoxy resin, and cresol novolac epoxy resin.

Further, the epoxy resin may include a polymer or oligomer having an epoxy group. The polymer or oligomer having an epoxy group may be, but not particularly limited to, a polymer of a vinyl monomer having an epoxy group or the like. Examples of the vinyl monomer having an epoxy group include (meth)acrylate monomers such as glycidyl (meth)acrylate, 3,4-epoxycyclohexylmethyl (meth)acrylate, and methylglycidyl (meth)acrylate.

Epoxy resin (A) may be a copolymer or cooligomer of a vinyl monomer having an epoxy group and another vinyl monomer or the like. Examples of another vinyl monomer include (meth)acrylates. The ester group of the (meth)acrylates may be methyl group, ethyl group, isopropyl group, normal butyl group, isobutyl group, tertiary butyl group, 2-ethylhexyl group, cyclohexyl group, benzyl group, isobornyl group, lauryl group, myristyl group, or the like. That is, the ester group is preferably a nonfunctional alkyl ester regardless of whether it has a linear structure or a branched structure. Furthermore, the epoxy resin may be a copolymer of a vinyl monomer having an epoxy group and styrene, α-methylstyrene, vinyl acetate, or the like.

Preferred specific examples of epoxy resin (A) contained in the surface sealing agent of the present invention include tetrafunctional naphthalene epoxy resin (A-a), triphenylmethane epoxy resin (A-b), dicyclopentadiene epoxy resin (A-c), ortho cresol novolac epoxy resin (A-d), phenol novolac epoxy resin (A-e), fluorene epoxy resin (A-f), and bisphenol trifunctional epoxy resin (A-g). The structural formula of an example of each epoxy resin is shown below.

### [Formula 6]

An example of tetrafunctional naphthalene epoxy resin (A-a)

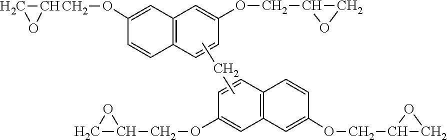

### [Formula 7]

An example of triphenylmethane epoxy resin (A-b)

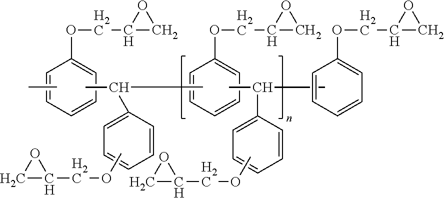

(where n represents an integer)

### [Formula 8]

An example of dicyclopentadiene epoxy resin (A-c)

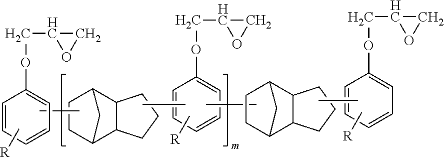

(where m represents an integer, and each R independently represents a C₁₋₅ alkyl group)

### [Formula 9]

An example of ortho-cresol novolac epoxy resin (A-d)

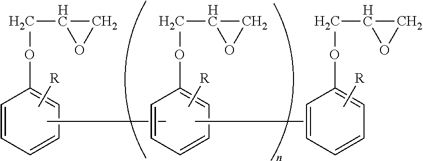

(where n represents an integer, and each R independently represents a C₁₋₅ alkyl group)

### [Formula 10]

An example of phenol novolac epoxy resin (A-e)

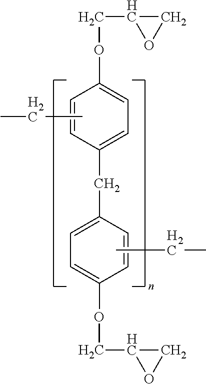

(where n represents an integer)

### [Formula 11]

An example of fluorene epoxy resin (A-f)

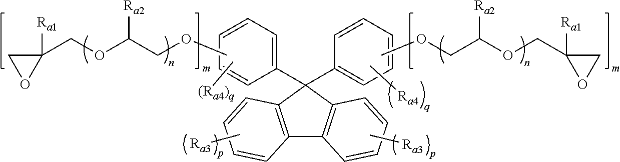

(where each Rₐ₁ independently represents a hydrogen atom or methyl group; each Rₐ₂ independently represents a hydrogen atom or methyl group; each Rₐ₃ independently represents a C₁₋₅ alkyl group; each Rₐ₄ independently represents a C₁₋₅ alkyl group; each n independently represents an integer of 0 to 3; each m independently represents an integer of 1 to 3; each p independently represents an integer of 0 to 4; and each q independently represents an integer of 0 to 4)

### [Formula 12]

An example of bisphenol trifunctional epoxy resin (A-g)

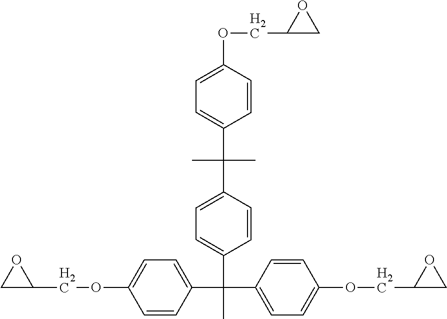 [SMILES: CC(C)(c1ccc(OCC2CO2)cc1)c1ccc(C(C)(c2ccc(OCC3CO3)cc2)c2ccc(OCC3CO3)cc2)cc1]

Since epoxy resins (A-a) to (A-g) have bulky groups (aryl groups), the heat resistance of cured products of the surface sealing agents containing these epoxy resins tends to increase. Further, the surface sealing agents containing such epoxy resins tend to have higher optical transparency and adhesion strength. Furthermore, it is easy to control the viscosity of the surface sealing agents containing these epoxy resins within a desired range (for example, 200 to 10,000 mPa·s as measured by an E-type viscometer at 25° C. and 1.0 rpm). Therefore, the surface sealing agent of the present invention can be easily formed into a film by screen printing or the like.

Moreover, epoxy resin (A) may include either one or both of high molecular weight phenol epoxy resin (A-1) and low molecular weight phenol epoxy resin (A-2). When epoxy resin (A) contains high molecular weight phenol epoxy resin (A-1) or low molecular weight phenol epoxy resin (A-2), a surface sealing agent containing epoxy resin (A) can be formed into a sheet.

High molecular weight phenol epoxy resin (A-1) is preferably a polymer or oligomer containing phenol resin and epichlorohydrin as monomer components, more preferably an oligomer containing the same as monomer components. The monomer components of high molecular weight phenol epoxy resin (A-1) may include only phenol resin and epichlorohydrin or may include a compound (comonomer component) other than the phenol resin and epichlorohydrin as a part of the monomer components. When a comonomer component is contained as a part of the monomer components, the weight average molecular weight (Mw) of high molecular weight phenol epoxy resin (A-1) to be obtained will easily fall within a desired range. Moreover, when the monomer components of high molecular weight phenol epoxy resin (A-1) are appropriately selected, the smoothness of the coating film surface of the surface sealing agent is improved.

The weight average molecular weight (Mw) of high molecular weight phenol epoxy resin (A-1) is preferably 3×10³ to 2×10⁴, more preferably 3×10³ to 7×10³. The “weight average molecular weight (Mw)” is measured by gel permeation chromatography (GPC) using polystyrene as a standard reference material.

When the weight average molecular weight (Mw) of high molecular weight phenol epoxy resin (A-1) is within the numerical value range as described above, a cured film having high adhesive strength and low moisture permeability is obtained. Moreover, a surface sealing agent containing high molecular weight phenol epoxy resin (A-1) wherein the weight average molecular weight (Mw) is within the numerical value range as described above is easily applied and easily formed into a sheet.

The epoxy equivalent of high molecular weight phenol epoxy resin (A-1) is preferably 500 to 10,000 g/eq.

Low molecular weight phenol epoxy resin (A-2) refers to a phenol epoxy resin having a weight average molecular weight of 200 to 800, more preferably a weight average molecular weight of 300 to 700. The “weight average molecular weight (Mw)” is measured by gel permeation chromatography (GPC) using polystyrene as a standard reference material.

Low molecular weight phenol epoxy resin (A-2) may be an oligomer containing, for example, bisphenol and epichlorohydrin as monomer components. Examples of phenol derivatives of the oligomer containing a phenol derivative and epichlorohydrin as monomer components include bisphenol, hydrogenated bisphenol, phenol novolac, and cresol novolac.

The repeated structural unit included in low molecular weight phenol epoxy resin (A-2) may be the same as or different from the repeated structural unit included in high molecular weight bisphenol epoxy resin (A-1).

Examples of low molecular weight bisphenol epoxy resin (A-2) include a compound represented by general formula (X), and preferred examples thereof include a compound represented by general formula (X′).

### [Formula 13]

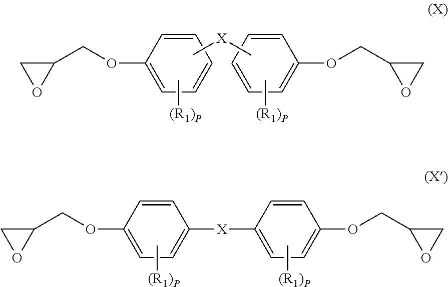

In general formula (X), X represents a single bond, a methylene group, an isopropylidene group, —S—, or —SO₂—; each R₁ independently represents a C₁₋₅ alkyl group; and P represents an integer of 0 to 4.

The epoxy equivalent of low molecular weight phenol epoxy resin (A-2) is preferably 100 to 800 g/eq.

When low molecular weight phenol epoxy resin (A-2) is contained, the fluidity of the resulting surface sealing agent increases, increasing the adhesion of the surface sealing agent to an organic EL element.

The proportions of high molecular weight phenol epoxy resin (A-1) and low molecular weight phenol epoxy resin (A-2) contained in a sheet-shaped surface sealing agent are not particularly limited; the composition of the surface sealing agent is preferably controlled so that a desired viscosity can be achieved. If the content of high molecular weight phenol epoxy resin (A-1) is excessively high, the moisture permeability of a cured film (sealing member) will increase. In addition, when the cured film is bonded to an organic EL element, the cured film will not sufficiently follow the shape of the organic EL element, and a gap is liable to be formed between the cured film and the organic EL element. On the other hand, if the content of high molecular weight phenol epoxy resin (A-1) is excessively low, the adhesive strength of the cured film will decrease.

The content of epoxy resin (A) in the surface sealing agent is preferably 70 to 99.9% by weight, more preferably 80 to 99.9% by weight, further preferably 90 to 99.9% by weight. When the content of epoxy resin (A) falls within the above-described range, the strength of the cured film of the surface sealing agent increases, and it is possible to protect an organic EL element from water, oxygen, and the like.

Curing Accelerator (B)

Curing accelerator (B) contained in the surface sealing agent of the present invention contains a salt (B1 or B2) containing a specific quaternary ammonium ion.

Salt (B1) contains a quaternary ammonium ion represented by the following general formula (1).

### [Formula 14]

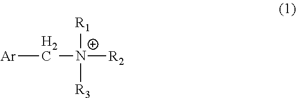

In general formula (1), R₁, R₂, and R₃ each independently represent a C₁₋₁₀ alkyl group which may have a substituent, a C₆₋₁₀ aryl group which may have a substituent, or a C₇₋₂₀ aralkyl group which may have a substituent. In particular, R₁, R₂, and R₃ are preferably each independently methyl group, phenyl group, or benzyl group.

The type of the substituent on R₁, R₂, and R₃ in general formula (1) is preferably, but not particularly limited to, a functional group selected from the group consisting of a C₁₋₁₀ alkyl group, a C₁₋₁₀ alkoxy group, F, Cl, Br, I, NO₂, CN, and a group represented by the following general formula (5).

### [Formula 15]

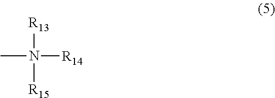

In the group represented by the above general formula (5) which may be a substituent on R₁, R₂, and R₃ in general formula (1), R₁₃, R₁₄, and R₁₅ each independently represent a hydrogen group or a C₁₋₁₀ hydrocarbon group, and all of R₁₃, R₁₄, and R₁₅ are preferably hydrocarbon groups. When all of R₁₃, R₁₄, and R₁₅ are hydrocarbon groups, the storage stability of the surface sealing agent increases. The hydrocarbon group may be a linear, branched or cyclic aliphatic group, or may be an aromatic group.

In general formula (1), Ar represents a C₆₋₁₀ aryl group which may have a substituent. Ar is preferably an aromatic hydrocarbon group and may be, for example, phenyl group, naphthyl group, or the like.

The type of the substituent bonded to Ar in general formula (1) is preferably, but not particularly limited to, a functional group selected from the group consisting of a C₁₋₁₀ alkyl group, a C₁₋₁₀ alkoxy group, F, Cl, Br, I, NO₂, CN, and a group represented by the following general formula (4), in terms of the stability or the like of the compound.

### [Formula 16]

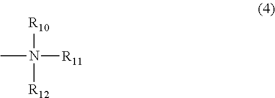

In the group represented by the above general formula (4) which may be a substituent bonded to Ar in general formula (1), R₁₀, R₁₁, and R₁₂ each independently represent a hydrogen group or a C₁₋₁₀ hydrocarbon group. All of R₁₀, R₁₁, and R₁₂ are particularly preferably hydrocarbon groups. When all of R₁₀, R₁₁, and R₁₂ are hydrocarbon groups, the storage stability of the surface sealing agent increases. The hydrocarbon group may be a linear, branched, or cyclic aliphatic group, or may be an aromatic group.

The bonding position of the substituent bonded to Ar in general formula (1) and the number of the substituents bonded to Ar are not particularly limited, and are suitably selected depending on the reactivity with epoxy resin (A) or the like. For example, when the substituent bonded to Ar is an electron-attracting group, that is, when the substituent bonded to Ar is F, Cl, Br, I, NO₂, or CN, the substituent is preferably bonded at a meta position or the para position relative to the bonding position of Ar and the methylene group in general formula (1). When an electron-attracting group is bonded at these positions, the curing reaction of epoxy resin (A) is easily accelerated. Moreover, the number of the electron-attracting groups bonded to Ar is preferably two or less.

On the other hand, when the substituent bonded to Ar is an electron-donating group, that is, when the substituent bonded to Ar is an alkyl group, an alkoxy group, or a group represented by the above general formula (5), the substituent is preferably bonded at the para position relative to the bonding position of Ar and the methylene group in general formula (1). When an electron-donating group is bonded at this position, the curing reaction of epoxy resin (A) is easily accelerated. The curing reaction of epoxy resin (A) is more easily accelerated when the substituent bonded to Ar is an electron-donating group than when it is an electron-attracting group.

Preferred examples of the quaternary ammonium ion represented by the above general formula (1) include the following ions.

### [Formula 17]

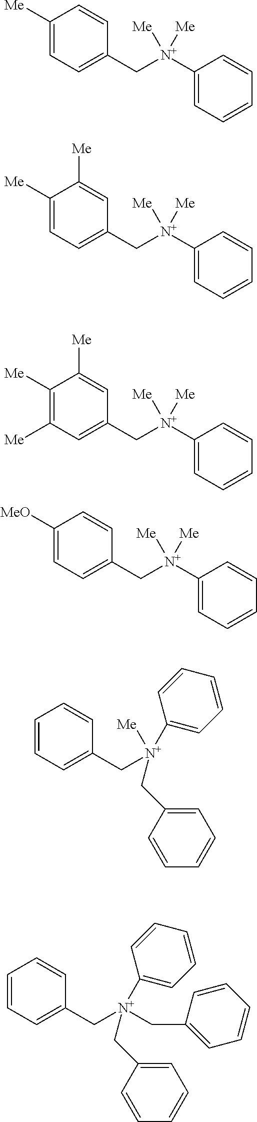 [SMILES: Cc1ccc(C[N+](C)(C)c2ccccc2)cc1 ; Cc1ccc(C[N+](C)(C)c2ccccc2)cc1C ; Cc1cc(C[N+](C)(C)c2ccccc2)cc(C)c1C ; COc1ccc(C[N+](C)(C)c2ccccc2)cc1 ; C[N+](Cc1ccccc1)(Cc1ccccc1)c1ccccc1 ; c1ccc(C[N+](Cc2ccccc2)(Cc2ccccc2)c2ccccc2)cc1]

Salt (B1) contains a quaternary ammonium ion represented by the above general formula (1) and a counter anion. Examples of the counter anion include [CF₃SO₃]⁻, [C₄F₉SO₃]⁻, [PF₆]⁻, [AsF₆]⁻, [Ph₄B]⁻, Cl⁻, Br⁻, I⁻, [OC(O)R₁₆]³¹ (where ₁₆ represents a C₁₋₁₀ alkyl group), [SbF₆]⁻, [B(C₆F₅)₄]₋, [B(C₆H₄CF₃)₄]⁻, [(C₆F₅)₂BF₂]⁻, [C₆F₅BF₃]⁻, and [B(C₆H₃F₂)₄]⁻. Among the above, preferred is an anion in which the logarithm of the reciprocal of the acid dissociation constant (pKa) is small. The smaller the pKa is, the more easily salt (B 1) is ionized to accelerate the curing reaction of epoxy resin.

Salt (B2) contains a quaternary ammonium ion represented by the following general formula (2).

### [Formula 18]

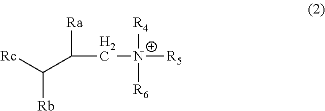

In the above general formula (2), R₄, R₅, and R₆ each independently represent a C₁₋₁₀ alkyl group which may have a substituent, a C₆₋₁₀ aryl group which may have a substituent, or a ⁷⁻²⁰ aralkyl group which may have a substituent. Among the above, methyl group, phenyl group, and benzyl group are particularly preferred. The type of the substituent on R₄, R₅, and R₆ in the above general formula (2) is not particularly limited and may be the same as the substituent on R₁, R₂, and R₃ in the above general formula (1).

In the above general formula (2), Ra, Rb, and Rc each independently represent a hydrogen group, a C₁₋₁₀ alkyl group, a C₁₋₁₀ alkoxy group, F, Cl, Br, I, NO₂, CN, or a group represented by the following general formula (3).

### [Formula 19]

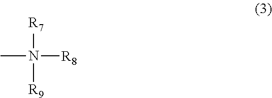

In the group represented by the above general formula (3) which may be Ra, Rb, or Rc in the above general formula (2), R₇, R₈, and R₉ each independently represent a hydrogen group or a C₁₋₁₀ hydrocarbon group. All of R₇, R₈, and R₉ are preferably hydrocarbon groups. When all of R₇, R₈, and R₉ are hydrocarbon groups, the storage stability of the surface sealing agent increases. The hydrocarbon group may be a linear, branched, or cyclic aliphatic group, or may be an aromatic group.

Salt (B2) contains a quaternary ammonium ion represented by the above general formula (2) and a counter anion. The counter anion may be the same as the counter anion contained in salt (B1).

The content of curing accelerator (B) is 0.1 to 10 parts by mass, preferably 0.1 to 5 parts by mass, more preferably 0.1 to 3 parts by mass, based on 100 parts by mass of the surface sealing agent. If the amount of curing accelerator (B) added is excessively small, epoxy resin (A) cannot be sufficiently cured. On the other hand, if the amount of curing accelerator (B) is excessive, unreacted curing accelerator (B) increases. This may increase the moisture permeability of the cured product of the surface sealing agent of the present invention, causing deterioration of an organic EL element. Curing accelerator (B) may contain only one compound or may be a combination of two or more compounds.

Moreover, the ratio of the amount of ammonium ions in curing accelerator (B) to the amount of epoxy groups contained in the surface sealing agent (equivalent ratio (the number of ammonium ions in curing accelerator (B)/the number of epoxy groups in the surface sealing agent)×100) is preferably 0.5 to 10%, more preferably 0.5 to 1%.

It is deduced that in the above curing accelerator (B), the quaternary ammonium ion contained in salt (B1) or salt (B2) reacts in the manner as shown in the following exemplary reaction scheme, whereby curing accelerator (B) accelerates the curing of epoxy resin. Hereinafter, description will be given by taking the reaction mechanism of the quaternary ammonium ion contained in salt (B1) as an example, but it is deduced that the quaternary ammonium ion contained in salt (B2) reacts similarly.

### [Formula 20]

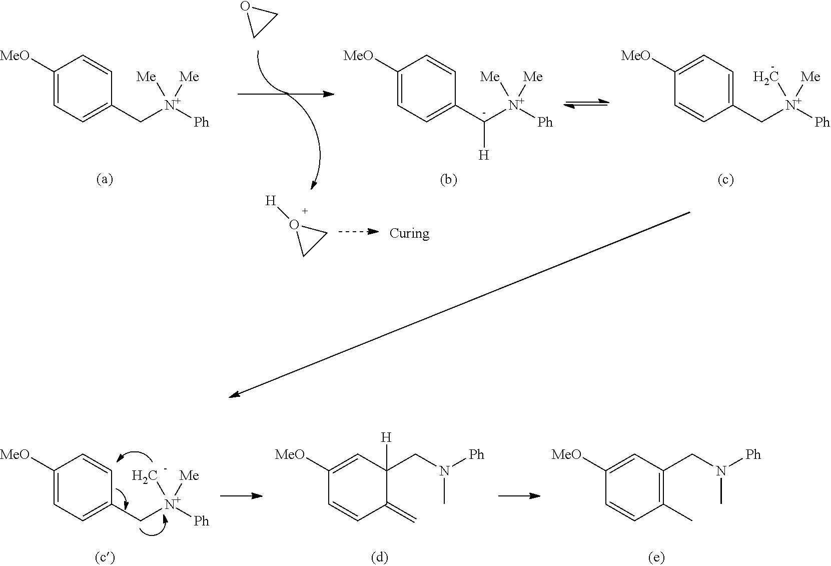

When the quaternary ammonium ion represented by the above formula (a) is heated, a proton at the benzylic position is dissociated, and the proton is donated to the epoxy group of epoxy resin (A). As a result, the above intermediate (b) is produced. This intermediate (b) is converted into compound (e) having a more stable structure through intermediate (c) and intermediate (d). On the other hand, the epoxy group of epoxy resin (A) to which the proton is donated from quaternary ammonium ion (a) is opened, and the epoxy resin is polymerized with other plurality of epoxy resins (A) to form a cured product.

In the above quaternary ammonium ion (a), the methylene group is adjacent to the aryl group having a π-bond. This ammonium ion (a) easily undergoes a transfer reaction (from intermediate (b) to (e)) at a certain temperature or higher. In addition, a proton at the benzylic position of ammonium ion (a) is dissociated to allow easy transfer to intermediate (b). On the other hand, at low temperatures, since the above transfer reaction does not easily proceed, the storage stability of the surface sealing agent is high.

When a common curing accelerator containing an aromatic compound such as imidazole is used together with an epoxy resin, an aromatic compound derived from the curing accelerator may be added to a terminal of the epoxy resin to cause coloring of the epoxy resin. On the other hand, when a functional group derived from the curing accelerator is added to a terminal of the epoxy resin, the backbone of the epoxy resin around the functional group is liable to be cleaved by plasma irradiation. That is, plasma resistance of a cured product of an epoxy resin decreases. By contrast, the quaternary ammonium ion (a) is less likely to be added to a terminal of an epoxy resin. Therefore, the epoxy resin is hardly colored, and the backbone of the epoxy resin is hardly cleaved by plasma irradiation.

The reactivity of the quaternary ammonium ion (a) can be controlled by a substituent on the aryl group adjacent to the methylene group. When the substituent on the aryl group is an electron-donating group, the reactions easily proceed from intermediate (b) to final product (e), increasing the reactivity of quaternary ammonium ion (a).

Coupling Agent (C)

The surface sealing agent of the present invention may contain a coupling agent (C) such as a silane coupling agent, a titanium coupling agent, a zirconium coupling agent, or an aluminum coupling agent. The surface sealing agent containing coupling agent (C) exhibits high adhesion to the substrate of an organic EL device and the like.

Examples of silane coupling agent (C) include 1) a silane coupling agent having an epoxy group, 2) a silane coupling agent having a functional group capable of reacting with an epoxy group, and 3) other silane coupling agents. Silane coupling agent (C) is preferably a silane coupling agent that reacts with epoxy resin (A) in the surface sealing agent. When silane coupling agent (C) reacts with epoxy resin (A), a low molecular weight component does not remain in a cured film. The silane coupling agent that reacts with epoxy resin (A) is preferably 1) a silane coupling agent having an epoxy group, or 2) a silane coupling agent having a functional group capable of reacting with an epoxy group. As used herein “reacting with an epoxy group” refers to, for example, undergoing addition reaction with an epoxy group.

1) The silane coupling agent having an epoxy group is a silane coupling agent containing an epoxy group such as glycidyl group, and examples thereof include γ-glycidoxypropyltrimetoxysilane and β-(3,4-epoxycyclohexyl)pethyltrimethoxysilane.

2) Examples of the functional group capable of reacting with an epoxy group include amino groups such as primary amino group and secondary amino group, carboxyl group, and groups to be converted into functional groups capable of reacting with an epoxy group (for example, methacryloyl group, and isocyanate group). Examples of such a silane coupling agent having a functional group capable of reacting with an epoxy group include N-2-(aminoethyl)-3-aminopropylmethyldimethoxysilane, N-2-(aminoethyl)-3-aminopropylmethyltrimethoxysilane, N-2-(aminoethyl)-3-aminopropylmethyltriethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane or 3-(4-methylpiperazino)propyltrimethoxysilane, trimethoxysilylbenzoic acid, γ-methacryloxypropyltrimethoxysilane and γ-isocyanatopropyltriethoxysilane.

Examples of 3) other silane coupling agents include vinyltriacetoxysilane and vinyltrimetoxysilane. These silane coupling agents may be contained in the surface sealing agent alone or in combination.

The molecular weight of silane coupling agent (C) contained in the surface sealing agent is preferably 80 to 800. If the molecular weight of silane coupling agent (C) exceeds 800, adhesion may decrease.

The content of silane coupling agent (C) in the surface sealing agent is preferably 0.05 to 30 parts by mass, more preferably 0.1 to 20 parts by mass, and further preferably 0.3 to 10 parts by mass, based on 100 parts by mass of the surface sealing agent.

Other Optional Components (D)

The surface sealing agent of the present invention may include other optional components (D) as long as the effect of the present invention is not impaired. Examples of other optional components (D) include a resin component, a filler, a modifier, an antioxidant, a stabilizer, and an acid anhydride.

Examples of the resin component include polyamide, polyamideimide, polyurethane, polybutadiene, polychloroprene, polyether, polyester, styrene-butadiene-styrene block copolymer, petroleum resin, xylene resin, ketone resin, cellulose resin, fluorine oligomer, silicon oligomer, and polysulfide oligomer. These resin components may be contained in the surface sealing agent alone or in combination.

Examples of the filler include glass beads, styrene polymer particles, methacrylate polymer particles, ethylene polymer particles, and propylene polymer particles. The filler may be contained in the surface sealing agent alone or in combination.

Examples of the modifier include a polymerization initiation auxiliary, an antiaging agent, a leveling agent, a wettability improver, a surfactant, and a plasticizer. These modifiers may be contained in the surface sealing agent alone or in combination.

Examples of the stabilizer include ultraviolet absorbers, preservatives, and antibacterial agents. These stabilizers may be contained in the surface sealing agent alone or in combination.

The antioxidant refers to an agent which deactivates radicals generated by plasma irradiation and sunlight irradiation (Hindered Amine Light Stabilizer, HALS), an agent which decomposes a peroxide, and the like. The antioxidant contained in the surface sealing agent limits the discoloration of a cured product of the surface sealing agent.

Examples of the hindered amine include bis(2,2,6,6-tetramethylpiperidin-4-yl)sebacate and bis(1,2,2,6,6-pentamethylpiperidin-4-yl)sebacate.

Examples of phenol antioxidants include monophenols such as 2,6-di-t-butyl-p-cresol and 2,6-di-t-butyl-4-ethylphenol; bisphenols such as 2,2′-methylenebis(4-methyl-6-t-butylphenol), 2,2′-methylenebis(4-ethyl-6-t-butylphenol), 4,4′-thiobis(3-methyl-6-t-butylphenol), and 4,4′-butylidenebis(3-methyl-6-t-butylphenol); and polymer-type phenols such as 1,1,3-tris(2-methyl-4-hydroxy-5-t-buthylphenyl)butane and 1,3,5 -trimethyl-2,4,6-tris(3,5-di-t-butyl-4-hydroxybenzyl)benzene.

As a phosphorus antioxidant, an antioxidant selected from phosphites and a discoloration inhibitor selected from oxaphosphaphenanthrene oxides are preferably used. Examples of the phosphites include trioctyl phosphite, dioctyl monodecyl phosphite, and didecyl monooctyl phosphite. Examples of the oxaphosphaphenanthrene oxides include 9,10-dihydro-9-oxa-10-phosphaphenanthrene-10-oxide.

Particularly, from the perspective of imparting resistance to ultraviolet rays to the cured product of the surface sealing agent, the antioxidant is preferably Tinuvin 123 (bis(1-octyloxy-2,2,6,6-tetramethyl-4-piperidyl)sebacate), Tinuvin 765 (a mixture of bis(1,2,2,6,6-pentamethyl-4-piperidyl)sebacate and methyl 1,2,2,6,6-pentamethyl-4-piperidyl sebacate), Hostavin PR25 (dimethyl 4-methoxybenzyl idenemalonate), Tinuvin 312 or Hostavin vsu (ethanediamide, N-(2-ethoxyphenyl)-N′-(2-ethylphenyl)), and CHIMASSORB 119 FL (N,N-bis(3-aminopropyl)ethylenediamine-2,4-bis[N-butyl-N-(1,2,2,6,6-pentamethyl-4-piperidyl)amino]-6-chloro-1,3,5-triazine condensate).

Solvent (E)

The surface sealing agent of the present invention may contain solvent (E). When solvent (E) is contained, each component is uniformly dispersed or dissolved. Solvent (E) may be an organic solvent of any type. Examples thereof include aromatic solvents such as toluene and xylene; ketone solvents such as acetone, methyl ethyl ketone, and methyl isobutyl ketone; ethers such as ether, dibutyl ether, tetrahydrofuran, dioxane, ethylene glycol monoalkyl ether, ethylene glycol dialkyl ether, propylene glycol, and dialkyl ether;

aprotic polar solvents such as N-methyl pyrrolidone, dimethylimidazolidinone, and dimethylformaldehyde; and esters such as ethyl acetate and butyl acetate. Particularly, from the perspective of easily dissolving high molecular weight epoxy resin (A), a ketone solvent (solvent having a keto group) such as methyl ethyl ketone is more preferred.

Physical Properties of Surface Sealing Agent

The water content of the surface sealing agent of the present invention is preferably 0.1% by mass or less, more preferably 0.06% by mass or less. An organic EL element is liable to be degraded by moisture. Therefore, it is preferred to reduce the water content of the surface sealing agent as much as possible. The water content of the surface sealing agent is determined by weighing about 0.1 g of a sample, heating it at 150° C. with a Karl Fischer moisture meter, and measuring the content of moisture produced at this time (solid evaporation method).

The reaction activity-developing temperature of the surface sealing agent of the present invention is suitably controlled depending on the heat-resistant temperature of the element to be surface-sealed, and is preferably 70 to 150° C., more preferably 80 to 110° C., and further preferably 90 to 100° C. The reaction activity-developing temperature is closely related to the curable temperature of the surface sealing agent. When the reaction activity-developing temperature is 150° C. or less, the surface sealing agent can be heat-cured at 150° C. or less, and the organic EL element may be hardly affected by the surface sealing with the surface sealing agent. On the other hand, when the reaction activity-developing temperature is 70° C. or more, the curing reaction of epoxy resin (A) hardly occurs during storage and transportation, improving storage stability. The rising peak temperature of the exothermic peak measured by differential scanning calorimetry (DSC) is taken as the reaction activity-developing temperature. The reaction activity-developing temperature is controlled by the type of epoxy resin (A) and the type of curing accelerator (B), and in particular, it is greatly dependent on the structure of the quaternary ammonium ion contained in curing accelerator (B).

When the surface sealing agent is liquid, the viscosity (the value measured by an E-type viscometer at 25° C. and 1.0 rpm) of the surface sealing agent is preferably 200 to 10,000 mPa·s. When the viscosity of the surface sealing agent is within the above range, coatability (for example, screen printability) is improved. In addition, the surface sealing agent is easily formed into a sheet. The viscosity of the surface sealing agent is measured by an E-type viscometer (RC-500, manufactured by Toki Sangyo Co., Ltd.).

The surface sealing agent of the present invention is produced by any method as long as the effect of the present invention is not impaired. For example, the surface sealing agent is produced through a step 1) of providing epoxy resin (A), curing accelerator (B), and other optional components, and a step 2) of mixing these components in an inert gas atmosphere at 30° C. or below. Examples of the mixing method include a method that involves charging the foregoing components in a flask followed by stirring, and a method that involves kneading the foregoing components with a three-roll mill. When the surface sealing agent of the present invention is formed into a sheet, for example, a liquid surface sealing agent may be applied to a peeling substrate, followed by drying and peeling the applied film. The surface sealing agent may be applied to a substrate by, for example, screen printing or dispenser coating.

The surface sealing agent of the present invention may be liquid or solid (sheet-shaped). A method of surface-sealing the organic EL element with a liquid surface sealing agent may be a method wherein the surface sealing agent is applied to an organic

EL element by screen printing, dispenser coating or the like, and then cured. On the other hand, a method of surface-sealing the organic EL element with a sheet-shaped surface sealing agent may be a method wherein the surface sealing agent is laminated on an organic EL element and cured.

The cured product of the surface sealing agent of the present invention preferably has high transmittance for visible light. The light transmittance at 380 nm in a wavelength region (visible and ultraviolet light) of a cured film obtained by curing the surface sealing agent having a film thickness of 10 pm at 100° C. for 30 minutes is preferably 80% or more, more preferably 90% or more, and further preferably 95% or more. When the light transmittance is 80% or more, the light emitted by an organic EL element can be efficiently out-coupled through the cured product of the surface sealing agent. However, when the surface sealing agent of the present invention is used for a back emission type organic EL element, the transparency of the cured product is not particularly limited.

2. Organic EL Device

The organic EL device of the present invention includes an organic EL element disposed on a display substrate, a counter substrate making a pair with the display substrate, and a sealing member which is present between the display substrate and the counter substrate and covers (surface-seals) the organic EL element.

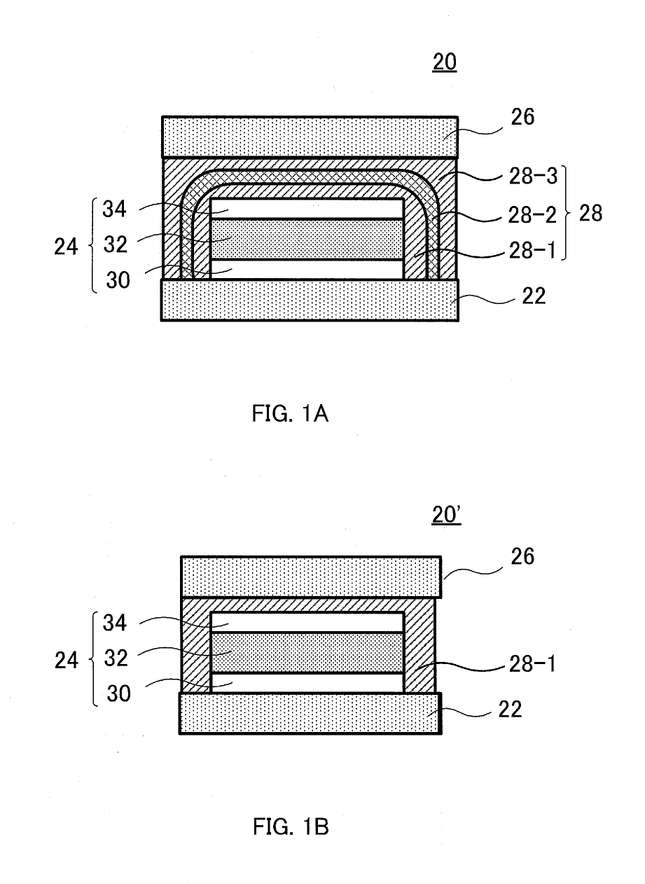

One embodiment of the organic EL device of the present invention is illustrated in the schematic sectional view of FIG. 1A. Organic EL device 20 of the present embodiment includes 1) organic EL element 24 disposed on display substrate 22, 2) sealing member 28-1 which is in contact with organic EL element 24 and covers (surface-seals) organic EL element 24, 3) passivation film 28-2 which is in contact with sealing member 28-1 and covers sealing member 28-1, 4) sealing material 28-3 covering passivation film 28-2, and 5) counter substrate 26 covering sealing material 28-3. Here, the cured product of the surface sealing agent as described above is used as sealing member 28-1.

Organic EL device 20 illustrated in FIG. 1A has display substrate 22, organic EL element 24, and counter substrate 26 laminated in the order presented. Surface sealing layer 28 is disposed between display substrate 22 and counter substrate 26, and surface sealing layer 28 covers (surface-seals) at least the main surface of organic EL element 24.

In organic EL device 20 illustrated in FIG. 1A, surface sealing layer 28 includes sealing member 28-1 made of a cured product of the surface sealing agent of the present invention, passivation film 28-2 covering sealing member 28-1, and sealing material 28-3 covering passivation film 28-2.

Display substrate 22 and counter substrate 26 are generally formed of a glass substrate or a resin film, and at least one of display substrate 22 and counter substrate 26 is formed of a transparent glass substrate or a transparent resin film. Examples of such a transparent resin film include an aromatic polyester resin such as polyethylene terephthalate.

When organic EL element 24 is a top emission type, organic EL element 24 includes pixel electrode layer 30 (made of aluminum, silver, or the like), organic EL layer 32, and counter electrode layer 34 (made of ITO, IZO, or the like) in the order presented from the side of display substrate 22. Pixel electrode layer 30, organic EL layer 32, and counter electrode layer 34 may be formed by vacuum deposition, sputtering, or the like.

Surface sealing layer 28 includes sealing member 28-1 made of a cured product of the surface sealing agent of the present invention, passivation film 28-2, and sealing material 28-3. Sealing member 28-1 is preferably in contact with organic EL element 24. The thickness of sealing member 28-1 is preferably 0.1 to 20 μm.

Passivation film 28-2 constituting surface sealing layer 28 may be an inorganic compound film to be formed, for example, in a plasma environment. Forming a film in a plasma environment refers to for example forming a film by plasma CVD. The material of passivation film 28-2 is preferably a transparent inorganic compound, and examples thereof include, but are not particularly limited to, silicon nitride, silicon oxide, SiONF, and SiON. The thickness of passivation film 28-2 is preferably 0.1 to 5 μm. Passivation film 28-2 may cover the entire surface of sealing member 28-1 or may cover only a part thereof.

In organic EL device 20, passivation film 28-2 is not in direct contact with organic EL element 24, but passivation film 28-2 is laminated on sealing member 28-1. When passivation film 28-2 is intended to be formed in direct contact with organic EL element 24, the coverage provided by passivation film 28-2 may be reduced since the edge of organic EL element 24 has an acute angle. On the other hand, when organic EL element 24 is surface-sealed by sealing member 28-1, and then passivation film 28-2 is formed on sealing member 28-1, the surface of passivation film 28-2 formed can be gently-sloping, thus improving the coverage. At this time, if the plasma resistance of sealing member 28-1 is low, the transparency of sealing member 28-1 may be reduced by the plasma irradiation during the lamination of passivation film 28-2. On the other hand, sealing member 28-1 made of the cured product of the surface sealing agent of the present invention has high plasma resistance. Therefore, high transparency is maintained even if sealing member 28-1 is irradiated with plasma.

Sealing material 28-3 constituting surface sealing layer 28 may be the same material (the cured product of the surface sealing agent of the present invention) as or a different material from the material of sealing member 28-1. For example, the moisture content of sealing material 28-3 may be higher than the moisture content of sealing member 28-1. This is because sealing material 28-3 is not in direct contact with organic EL element 24. Moreover, in the case of top emission organic EL device 20 (organic EL device which takes out the emission of an organic EL element through sealing material 28-3), the optical transmittance of sealing material 28-3 may be required to be as high as that of sealing member 28-1.

Here, in organic EL device 20 illustrated in FIG. 1A, sealing member 28-1 and passivation film 28-2 are disposed so as to be in contact with each other; but an additional layer (not shown) covering a part of sealing member 28-1 may be present between sealing member 28-1 and passivation film 28-2, if needed. Also in such a configuration, if a passivation film is formed on the additional layer, a part of sealing member 28-1 which is not covered with the additional layer will be irradiated with plasma. As described above, sealing member 28-1 made of the cured product of the surface sealing agent of the present invention has high plasma resistance. Therefore, high transparency is maintained even if sealing member 28-1 is irradiated with plasma.

Another embodiment of the organic EL device of the present invention is illustrated in the schematic sectional view of FIG. 1B. Organic EL device 20′ of the present embodiment includes 1) organic EL element 24 disposed on display substrate 22, 2) sealing member 28-1 which is in contact with organic EL element 24 and covers (surface-seals) organic EL element 24, and 3) counter substrate 26 covering sealing member 28-1. Here, sealing member 28-1 is formed of the cured product of the surface sealing agent as described above.

Organic EL device 20′ illustrated in FIG. 1B has display substrate 22, organic EL element 24, and counter substrate 26 laminated in the order presented. Sealing member 28-1 is disposed between display substrate 22 and counter substrate 26, and sealing member 28-1 covers (surface-seals) around the surface of organic EL element 24. Other components of organic EL device 20′ illustrated in FIG. 1B are the same as the components of organic EL device 20 illustrated in FIG. 1A.

The organic EL device of the present invention may be manufactured by any method as long as the effect of the present invention is not impaired, and the effect of the surface sealing agent of the present invention is particularly effectively exhibited when the manufacturing method includes 1) preparing an organic EL element disposed on a substrate, 2) covering the organic EL element with a surface sealing agent, and 3) heat-curing the surface sealing agent. Moreover, the method may include the step of forming a passivation film on the cured product of the surface sealing agent. As described above, the surface sealing agent of the present invention has high weather resistance and high plasma resistance. Thus, a passivation film can be formed on the cured product of the surface sealing agent by plasma CVD or the like.

The surface sealing agent of the present invention can be cured at a relatively low curing temperature. The heat-curing temperature may be a temperature at which curing accelerator (B) in the surface sealing agent is activated, and is preferably 70 to 150° C., more preferably 80 to 110° C., and further preferably 90 to 100° C. At a temperature of less than 70° C., curing accelerator (B) cannot sufficiently be activated, and curing of epoxy resin (A) may be insufficient. If the temperature exceeds 150° C., the organic EL element may be affected during the heat-curing.

Heat-curing can be performed by any of the methods known in the art, e.g., heating in an oven or on a hot plate. Heating time is preferably 30 to 120 minutes, more preferably 30 to 90 minutes, and further preferably 30 to 60 minutes.

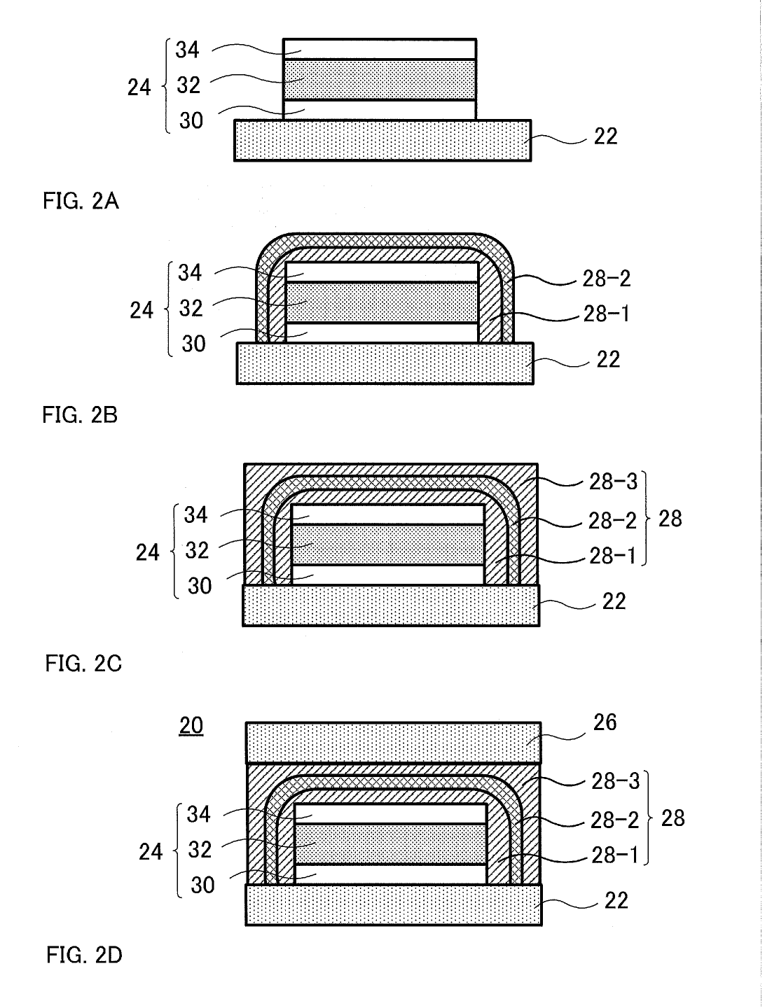

FIGS. 2A to 2D schematically illustrate an example of a process for manufacturing the surface-sealed organic EL device of the present invention. First, display substrate 22 on which organic EL element 24 is laminated is prepared (FIG. 2A). Organic EL element 24 includes pixel electrode layer 30, organic EL layer 32, and counter electrode layer 34, and may further include an additional functional layer. Next, a laminate is prepared in which a passivation film is formed on the sheet-shaped surface sealing agent of the present invention. Passivation film (transparent inorganic compound layer) 28-2 can be formed by any method, such as plasma CVD. This laminate is laminated on organic EL element 24 which is laminated on display substrate 22 (so as to cover counter electrode layers 34). The lamination is performed so that organic EL element 24 and the surface sealing agent may face each other. Subsequently, the surface sealing agent is cured to form sealing member 28-1 (FIG. 2B).

Next, passivation film 28-2 is covered with a resin layer (FIG. 2C), and counter substrate 26 is disposed thereon. In this state the resin layer is cured to form sealing material 28-3, and thereon is bonded counter substrate 26 (FIG. 2D). Organic EL device 20 of the present invention is obtained in this way.

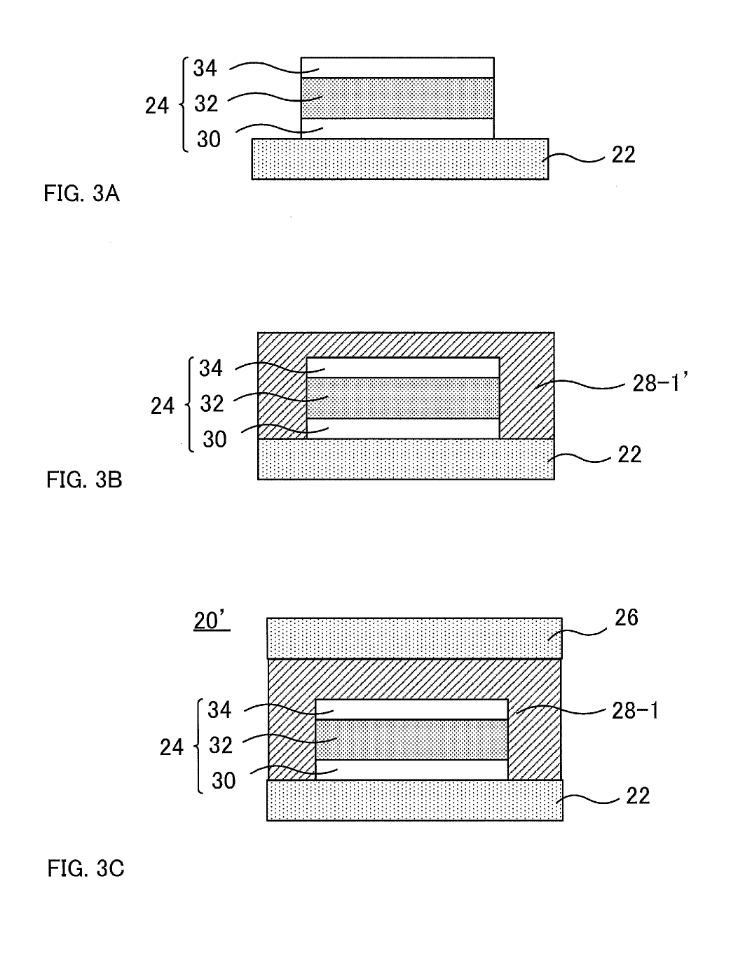

FIGS. 3A to 3C schematically illustrate another example of a process for manufacturing the surface-sealed organic EL device of the present invention. First, display substrate 22 on which organic EL element 24 is laminated is prepared (FIG. 3A). Organic EL element 24 includes pixel electrode layer 30, organic EL layer 32, and counter electrode layer 34, and may further include an additional functional layer. Next, liquid surface sealing agent 28-1′ of the present invention in a sheet form is applied to organic EL element 24, or sheet-shaped surface sealing agent 28-1′ is laminated on organic EL element 24 which is laminated on display substrate 22 (FIG. 3B). Subsequently, counter substrate 26 is disposed thereon. In this state the surface sealing agent is cured to form sealing member 28-1, and then counter substrate 26 is bonded (FIG. 3C). Organic EL device 20′ of the present invention is obtained in this way.

FIGS. 2A to 2D and FIGS. 3A to 3C illustrate the flows in which one organic EL element 24 is formed on display substrate 22 and then sealed. However, it is also possible to seal a plurality of organic EL elements 24 formed on display substrate 22 in a single flow according to the same procedure.

### EXAMPLES

### Raw Materials

Hereinafter, raw materials added to the surface sealing agents in Examples and

Comparative Examples are shown below.

### <Epoxy Resin>

Bisphenol F epoxy resin: molecular weight: 338 (YL-983U, manufactured by Japan Epoxy Resins Co., Ltd.)

Trifunctional epoxy resin: molecular weight: 592 (VG-3101L, manufactured by Printec Co.)

<Curing Accelerator>

Quaternary ammonium salt (1) represented by the following formula (manufactured by King Industries, Inc.)

### [Formula 21]

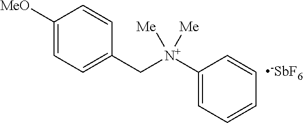

Quaternary ammonium salt (2) represented by the following formula (manufactured by King Industries, Inc.)

### [Formula 22]

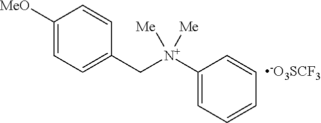

Quaternary ammonium salt (3) represented by the following formula (manufactured by King Industries, Inc.)

### [Formula 23]

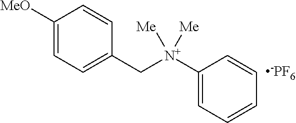

1-Benzyl-2-phenylimidazole (Curezol 1B2PZ, manufactured by Shikoku Chemicals Corporation)

1-Benzyl-2-methylimidazole (Curezol 1B2MZ, manufactured by Shikoku Chemicals Corporation)

2-Ethyl-4-methylimidazole (Curezol 2E4MZ, manufactured by Shikoku Chemicals Corporation)

<Acid Anhydride>

A mixture of methylhexahydrophthalic anhydride and hexahydrophthalic anhydride (RIKACID MH-700, manufactured by New Japan Chemical Co., Ltd.)

### <Silane Coupling Agent>

3-Glycidoxypropyltrimethoxysilane (KBM-403, the number of alkoxy groups per a molecule: 3, molecular weight: 236.3, manufactured by Shin-Etsu Chemical Co., Ltd.)

### Example 1

In a flask purged with nitrogen, 100 parts by weight of an epoxy resin, 2 parts by weight of a quaternary ammonium salt (1), and 4 parts by weight of a silane coupling agent were mixed at 50° C. with stirring to obtain a surface sealing agent.

### Examples 2 to 4 and Comparative Examples 1 to 5

Surface sealing agents were obtained in the same manner as in Example 1 except that epoxy resins, acid anhydrides, curing accelerators, and silane coupling agents were added in the ratios shown in Table 1.

Storage stability, light transmittance, reaction activity-developing temperature, plasma resistance, and curability of the surface sealing agents obtained in Examples 1 to 4 and Comparative Examples 1 to 5 were measured by the following methods.

### Storage Stability

The viscosity of the surface sealing agent was measured by an E-type viscometer (RC-500, manufactured by Toki Sangyo Co., Ltd.) at 25° C. and 1.0 rpm. The measurement was performed for a freshly prepared sample, a sample after storage at 25° C. for 24 hours, and a sample after storage at 25° C. for 48 hours. The measurement results are shown in Table 1.

### Light Transmittance

The light transmittance (background data) in a wavelength region of 190 nm to 800 nm (visible and ultraviolet light) of a non-alkali glass plate was measured. The surface sealing agent was screen-printed on the same non-alkali glass plate in a film thickness of 20 μm, and the film was heat-cured at 100° C. for 30 minutes. The light transmittance in a wavelength region of 190 nm to 800 nm (visible and ultraviolet light) of the cured product was measured. Subsequently, the background data was subtracted from the light transmittance data of the cured product to calculate the light transmittance of the cured product of the surface sealing agent. The evaluation was performed by the light transmittance at 380 nm.

### Reaction Activity-Developing Temperature

For measuring reaction activity-developing temperature, a plurality of surface sealing agent layers was thermocompression-bonded on a hot plate set to 45° C. to form a sheet having a thickness of 250 to 300 μm. The resulting sheet was measured for the rising peak temperature of the exothermic peak at a measurement frequency of 1 Hz, a heating rate of 4° C./minute, and a measurement temperature in the range of 40 to 150° C. with a rheometer manufactured by Haake Inc. (RS150 type), and the resulting temperature was taken as the reaction activity-developing temperature.

### Plasma Resistance

The surface sealing agent was printed with a screen printer (Screen Printer Model 2200, manufactured by MITANI Micronics Co., Ltd.) on a glass substrate (7 cm×7 cm×0.7 mm in thickness) previously washed by ozone treatment. The printing was performed so that the surface sealing agent in a dry state has a size of 5 cm×5 cm×3 μm in thickness. The glass substrate on which the surface sealing agent was printed was heated on a hot plate heated to 150° C. for 30 minutes to cure the surface sealing agent.

The haze value (%) of the cured product of the surface sealing agent was measured with a haze meter (model TC-H3DPK, manufactured by Tokyo Denshoku Co., Ltd.). Subsequently, the glass substrate having the cured product of the surface sealing agent thereon was set in a plasma treatment apparatus (model PDC210, parallel plate type, manufactured by Yamato Scientific Co., Ltd.), and plasma treatment was carried out for 20 minutes at an oxygen flow rate of 20 mL/minute and an RF power of 500 W. The haze value (%) of the cured product of the surface sealing agent after plasma treatment was measured with a haze meter (model TC-H3DPK, manufactured by Tokyo Denshoku Co., Ltd.).

An increase in the haze value after plasma treatment relative to the haze value before plasma irradiation ((haze value after treatment/haze value before treatment)×100−100) was calculated, and plasma resistance was evaluated by percent change. The smaller the change is, the higher the resistance to plasma. The change is shown in Table 1.

By carrying out plasma treatment and evaluating changes in haze in this way, it is possible to evaluate whether or not a surface sealing agent is applicable to a method for manufacturing an organic EL element including the step of irradiating the surface sealing agent with plasma. Further, accelerated evaluation of weather resistance of the surface sealing agent of an organic EL element can be carried out by plasma treatment.

### Curability

A surface sealing agent was sealed between two NaCl crystal plates (2-cm square and 5 mm in thickness) so that the spacing between the NaCl crystal plates is 15 μm. The infrared transmission spectrum of this sample was measured with an FT-IR spectrometer. Then, the sample was heat-treated at 150° C. for 30 minutes, and the infrared transmission spectrum of the heat-treated sample was similarly measured with an FT-IR spectrometer. The height of the absorption peak (near 910 cm⁻¹) assigned to the asymmetric ring stretching of an epoxy group in each measured spectrum was normalized by dividing it by the height of the absorption peak (near 1,600 cm⁻¹) assigned to the endocyclic C—C stretching of a benzene ring.

Epoxy conversion {(x1−x2)/x1}×100 (%) was calculated, where x1 represents the normalized value of the epoxy group peak before heat treatment, and x2 represents the normalized value of the epoxy group peak after heat treatment. The curability of the surface sealing agent was evaluated by the epoxy conversion. The higher the epoxy conversion is, the higher the curability. The epoxy conversion is shown in Table 1.

TABLE 1

| | | | | | | | Comparative |
|---|---|---|---|---|---|---|---|
| | | | Example 1 | Example 2 | Example 3 | Example 4 | Example 1 |
| Composition | Epoxy resin | YL-983U | 100 | 100 | 100 | 100 | 40 |
| | | VG-3101L | | | | | 60 |
| | Curing | Quaternary ammonium salt (1) | 2 | | | 2 | |
| | accelerator | Quaternary ammonium salt (2) | | 1.6 | | | |
| | | Quaternary ammonium salt (3) | | | 1.6 | | |
| | | 1-Benzyl-2-phenylimidazole | | | | | |
| | | 1-Benzyl-2-methylimidazole | | | | | |
| | | 2-Ethyl-4-methylimidazole | | | | | 3 |
| | | Acid anhydride (MH700) | 0 | 0 | 0 | 5 | 84 |
| | Silane coupling | KBM403 | 4 | 4 | 4 | 4 | 4 |
| | agent | | | | | | |
| Evaluation | Storage stability | Viscosity immediately | 4676 | 4471 | 3988 | 2756 | 7200 |
| | | after production (mPa · s) | | | | | |
| | | Viscosity after a lapse | Not measured | 4460 | 5360 | 2961 | 26290 |
| | | of 24 hours (mPa · s) | | | | | |
| | | Viscosity after a lapse | 4727 | 4479 | 5490 | 3007 | — |
| | | of 48 hours (mPa · s) | | | | | |

| | | | | | |
|---|---|---|---|---|---|
| Light transmittance (%) | 92 | 99 | 98 | 96 | 95 |
| Reaction activity-developing temperature (° C.) | 90 | 140 | 120 | 90 | 70 |
| Plasma resistance (%) | 17.1 | 0.3 | Not | Not | 39.1 |
| | | | measured | measured | |
| Curability (Epoxy conversion) (%) | 96.6 | 92.9 | Not | Not | 98.9 |
| | | | measured | measured | |

| | | | Comparative | Comparative | Comparative | Comparative |
|---|---|---|---|---|---|---|
| | | | Example 2 | Example 3 | Example 4 | Example 5 |
| Composition | Epoxy resin | YL-983U | 40 | 40 | 100 | 100 |
| | | VG-3101L | 60 | 60 | | |
| | Curing | Quaternary ammonium salt (1) | | | | |
| | accelerator | Quaternary ammonium salt (2) | | | | |
| | | Quaternary ammonium salt (3) | | | | |
| | | 1-Benzyl-2-phenylimidazole | | 3 | 3 | 3 |
| | | 1-Benzyl-2-methylimidazole | 3 | | | |
| | | 2-Ethyl-4-methylimidazole | | | | |
| | | Acid anhydride (MH700) | 84 | 84 | 40 | 5 |
| | Silane coupling | KBM403 | 4 | 4 | 4 | 4 |
| | agent | | | | | |
| Evaluation | Storage stability | Viscosity immediately | 5380 | 3873 | 2614 | >20000 |
| | | after production (mPa · s) | | | | |
| | | Viscosity after a lapse | 13800 | 7200 | 16370 | — |
| | | of 24 hours (mPa · s) | | | | |
| | | Viscosity after a lapse | — | — | — | — |
| | | of 48 hours (mPa · s) | | | | |

| | | | | |
|---|---|---|---|---|
| Light transmittance (%) | 95 | 95 | 63 | 29 |
| Reaction activity-developing temperature (° C.) | 70 | 70 | — | — |
| Plasma resistance (%) | Not measured | Not measured | Not measured | Not measured |
| Curability (Epoxy conversion) (%) | Not measured | Not measured | Not measured | Not measured |

As for the surface sealing agents in Examples 1 to 4 each containing a curing accelerator containing a quaternary ammonium salt, the viscosity immediately after production and the viscosity after storage for 48 hours did not greatly change, showing good storage stability. On the other hand, as for the surface sealing agents each containing a curing accelerator in which an acid anhydride is combined with other compounds, the viscosity after storage for 24 hours was more than twice the viscosity immediately after production (Comparative Examples 1 to 4). That is, the epoxy resin reacted during the storage, increasing the viscosity. In the curing accelerator in which an acid anhydride is combined with other compounds, when the amount of acid anhydride is small, the reaction proceeded in the process of stirring and mixing each component, increasing the viscosity of the surface sealing agent itself to a very high level (Comparative Example 5).

The surface sealing agent in Examples 1 to 4 each containing a curing accelerator containing a quaternary ammonium salt had a relatively low reaction activity-developing temperature of 90° C. to 140° C. and was able to be sufficiently cured in this temperature range. It can be said that the curability of these surface sealing agents is good also from the fact that all the epoxy conversions of the surface sealing agents in Examples 1 and 2 are higher than 90%.

The cured products of the surface sealing agents in Examples 1 to 4 each containing a curing accelerator containing a quaternary ammonium salt all had a light transmittance at 380 nm of 90% or more, showing high optical transparency. The cured products of the surface sealing agents in Example 1 and Example 2 exhibited small haze reduction by plasma irradiation, showing excellent weather resistance and plasma resistance.

### Industrial Applicability

The organic EL device having an organic EL element which is surface-sealed by the cured product layer of the surface sealing agent of the present invention has high optical transparency of the cured product layer. Moreover, since the surface sealing agent of the present invention can be cured at low temperatures, the organic EL element may hardly be damaged when the organic EL element is surface-sealed. In addition, the surface sealing agent of the present invention is excellent in storage stability.

### Reference Signs List

20 20′ Organic EL device
22 Display substrate
24 Organic EL element
26 Counter substrate
28 Surface sealing layer
28-1 Sealing member
28-2 Passivation film
28-3 Sealing material
28-1′ Surface sealing agent
30 Pixel electrode layer
32 Organic EL layer
34 Counter electrode Layer

1. A surface sealing agent for an organic EL element, comprising:
an epoxy resin (A) having two or more epoxy groups in a molecule; and
a curing accelerator (B) comprising at least one compound selected from the group consisting of a salt (B1) of a quaternary ammonium ion represented by the following general formula (1):
[Formula 1] 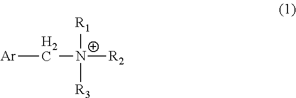
(wherein R₁, R₂, and R₃ each independently represent a C₁₋₁₀ alkyl group which may have a substituent, a C₆₋₁₀ aryl group which may have a substituent, or a C₇₋₂₀ aralkyl group which may have a substituent, and Ar represents a C₆₋₁₀ aryl group which may have a substituent) and a salt (B2) of a quaternary ammonium ion represented by the following general formula (2):
[Formula 2] 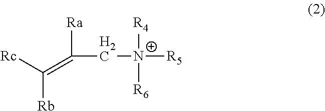
(wherein R₄, R₅, and R₆ each independently represent a C₁₋₁₀ alkyl group which may have a substituent, a C₆₋₁₀ aryl group which may have a substituent, or a C₇₋₂₀ aralkyl group which may have a substituent, and Ra, Rb, and Rc each independently represent a hydrogen group, a C₁₋₁₀ alkyl group, a C₁₋₁₀ alkoxy group, F, Cl, Br, I, NO₂, CN, or a group represented by the following general formula (3):
[Formula 3] 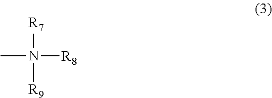
(wherein R₇, R₈, and R₉ each independently represent a hydrogen group or a C₁₋₁₀ hydrocarbon group), wherein
0.1 to 10 parts by weight of the curing accelerator (B) is contained based on 100 parts by weight of the surface sealing agent.

2. The surface sealing agent according to claim 1, wherein a substituent bonded to Ar in the general formula (1) is a functional group selected from the group consisting of a C₁₋₁₀ alkyl group, a C₁₋₁₀ alkoxy group, F, Cl, Br, I, NO₂, CN, and a group represented by the following general formula (4):
[Formula 4] 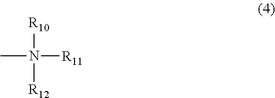
(wherein R₁₀, R₁₁, and R₁₂ each independently represent a hydrogen group or a C₁₋₁₀ hydrocarbon group).

3. The surface sealing agent according to claim 2, wherein a substituent bonded to Ar in the general formula (1) is a functional group selected from the group consisting of a C₁₋₁₀ alkyl group, a C₁₋₁₀ alkoxy group, and a group represented by the general formula (4).

4. The surface sealing agent according to claim 1, wherein a substituent on R₁, R₂, and R₃ in the general formula (1) and a substituent on R₄, R₅, and R₆ in the general formula (2) are each independently a functional group selected from the group consisting of a C₁₋₁₀ alkyl group, a C₁₋₁₀ alkoxy group, F, Cl, Br, I, NO₂, CN, and a group represented by the following general formula (5):
[Formula 5] 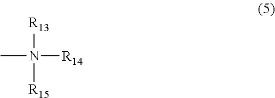
(wherein R₁₃, R₁₄, and R₁₅ each independently represent a hydrogen group or a C₁₋₁₀ hydrocarbon group).

5. The surface sealing agent according to claim 1, wherein a counter anion of the salt (B1) or the salt (B2) is selected from the group consisting of [CF₃SO₃]⁻, [C₄F₉SO₃]⁻, [PF₆]⁻, [AsF₆]⁻, [Ph₄B]⁻, Cl⁻, Br⁻, I⁻, [OC(O)R₁₆]³¹ (where ₁₆ represents a C₁₋₁₀ alkyl group), [SbF₆]⁻, [B(C₆F₅)₄]₋, [B(C₆H₄CF₃)₄]⁻, [(C₆F₅)₂BF₂]⁻, [C₆F₅BF₃]⁻, and [B(C₆H₃F₂)₄]⁻.

6. The surface sealing agent according to claim 1, further comprising a silane coupling agent (C).

7. A cured product of the surface sealing agent according to claim 1.

8. An organic EL device, comprising:
a display substrate on which an organic EL element is disposed;
a counter substrate making a pair with the display substrate; and
a sealing member which is present between the display substrate and the counter substrate and seals the organic EL element, wherein
the sealing member is a cured product according to claim 7.

9. An organic EL panel comprising the organic EL device according to claim 8.

10. A method for manufacturing an organic EL device, comprising:
providing a display substrate on which an organic EL element is disposed;
covering the organic EL element with a surface sealing agent according to claim 1; and
heat-curing the surface sealing agent.

11. The method for manufacturing an organic EL device according to claim 10, further comprising forming a passivation film on the cured product of the surface sealing agent.

12. An organic EL device, comprising:
an organic EL element;
a cured product layer which is in contact with the organic EL element and surface-seals the organic EL element, the cured product layer comprising a cured product of a surface sealing agent according to claim 1; and
a passivation film in contact with the cured product layer.
